(19) United States
(12) Patent Application Publication
(10) Pub. No.: US 2012/0071002 A1
(43) Pub. Date: Mar. 22, 2012

(54) METHOD OF MANUFACTURING SEMICONDUCTOR DEVICE AND SUBSTRATE PROCESSING APPARATUS

(75) Inventor: Masanori NAKAYAMA, Toyama (JP)

(73) Assignee: HITACHI KOKUSAI ELECTRIC INC., Tokyo (JP)

(21) Appl. No.: 13/232,587

(22) Filed: Sep. 14, 2011

(30) Foreign Application Priority Data
Sep. 17, 2010 (JP) 2010209816
Jul. 7, 2011 (JP) 2011151045

(51) Int. Cl. H01L 21/31

(52) U.S. Cl. 438/758; 257/E21.24

(57) ABSTRACT

A process of manufacturing a semiconductor device may be simplified, and oxidation of a metal element-containing film may be suppressed. The method of manufacturing a semiconductor device includes loading a substrate including a metal element-containing film and an insulating film formed on the metal element-containing film into a process chamber and supporting the substrate using a substrate support installed in the process chamber; supplying a reactive gas including at least one of hydrogen in excited state and nitrogen in excited state, and oxygen in excited state onto the substrate in the process chamber and processing the substrate; and unloading the substrate from an inside of the process chamber.

### CROSS-REFERENCE TO RELATED APPLICATIONS

This application claims priority to and the benefit of Japanese Patent Application Nos. 2010-209816 filed on Sep. 17, 2010 and 2011-151045 filed on Jul. 07, 2011, the disclosures of which are incorporated herein by reference.

1. Field of the Invention

The present invention relates to a method of manufacturing a semiconductor device, which processes a substrate using plasma, and a substrate processing apparatus.

2. Description of the Related Art

A method of manufacturing a semiconductor device having a capacitor structure such as a dynamic random access memory (DRAM) includes a process of forming a titanium nitride film (hereinafter, referred to as a “TiN film”) serving as a metal element-containing film, which is a lower electrode, on a substrate such as a silicon wafer, and a process of forming a high dielectric constant film (hereinafter, referred to as a “high-k film”) serving as a capacitor insulating film on the TiN film. The TiN film is, for example, formed by supplying a Ti source such as titanium tetrachloride (TiCl₄) gas and a nitriding agent such as ammonia (NH₃) gas onto the substrate. Also, the high-k film is, for example, formed by supplying a metal element-containing gas, which is obtained by vaporizing an organic metal material, and an oxidant such as oxygen (O₂) gas or ozone (O₃) gas onto the substrate.

### Prior-art Document

### [Patent Document]

1. Japanese Patent Laid-open Publication No. 2010-199576

2. Japanese Patent Laid-open Publication No. 2001-44387

3. Japanese Patent Laid-open Publication No. Hei 11-214385

### SUMMARY OF THE INVENTION

In the related art, for the purpose of removal of impurities remaining in a TiN film and recovery of etching damage caused in the TiN film, a process of modifying the TiN film using plasma has been performed before forming a high-k film. Also, there has been a demand to improve film quality of the high-k film as performances of a semiconductor device are improved. However, since the high-k film which is about to be formed does not show sufficient film quality due to the relationship of temperature conditions, a modification process using plasma has been performed after formation of the high-k film.

As such, in the case of the related art, modification processes have been performed at least after formation of the TiN film and formation of the high-k film, respectively. Therefore, the number of processes in a process of manufacturing a semiconductor device has increased and the process has become complicated, resulting in an increase in manufacturing cost of the semiconductor device.

Also, an oxidant such as oxygen gas or ozone gas is used to form the high-k film as described above. However, since the TiN film whose modification process is completed may be oxidized by the oxidant, a modification effect on the TiN film may be reduced when the high-k film is formed.

In addition, in the modification process of the high-k film, the high-k film is oxidized by supplying a gas containing an oxygen radical (O*) to the high-k film. However, since the oxygen radical (O*) may reach the TiN film via the high-k film, the TiN film may be oxidized, which leads to an increase in resistance value and thus performance degradation of the semiconductor device. Accordingly, in the modification process of the high-k film, processing conditions should be controlled in a very strict manner.

An object of the present invention is to provide a method of manufacturing a semiconductor device and a substrate processing apparatus, which are capable of simplifying a process of manufacturing a semiconductor device since a metal element-containing film and an insulating film may be modified together by performing a modification process on the metal element-containing film and the insulating film together after formation of the insulating film, rather than modification processes which have been performed, respectively, after formation of the metal element-containing film and after formation of the insulating film. Also, the present invention may provide a method of manufacturing a semiconductor device and a substrate processing apparatus, which are capable of preventing oxidation of the metal element-containing film.

According to one aspect of the present invention, there is provided a method of manufacturing a semiconductor device, including: loading a substrate having thereon a metal element-containing film and an insulating film formed on the metal element-containing film into a process chamber and supporting the substrate using a substrate support installed in the process chamber; supplying a reactive gas including at least one of hydrogen in excited state and nitrogen in excited state, and oxygen in excited state onto the substrate in the process chamber and processing the substrate; and unloading the substrate from an inside of the process chamber.

According to another aspect of the present invention, there is provided a substrate processing apparatus including: a process chamber wherein a substrate including a metal element-containing film and an insulating film formed on the metal element-containing film is loaded; a substrate support configured to support and heat the substrate in the process chamber; a gas introduction unit configured to supply a reactive gas including at least one of hydrogen in excited state and nitrogen in excited state, and oxygen in excited state into the process chamber; a plasma generation unit configured to excite the reactive gas in the process chamber; and a control unit configured to control the substrate support, the gas introduction unit and the plasma generation unit.

According to a method of manufacturing a semiconductor device and a substrate processing apparatus of the present invention, a process of manufacturing a semiconductor device can be simplified since a metal element-containing film and an insulating film may be modified together by performing a modification process on the metal element-containing film and the insulating film together after formation of the insulating film, rather than modification processes which have been performed, respectively, after formation of the metal element-containing film and after formation of the insulating film. Also, oxidation of the metal element-containing film can be prevented.

### BRIEF DESCRIPTION OF THE DRAWINGS

FIG. 1 is a schematic cross-sectional view of a substrate processing apparatus according to one embodiment of the present invention.

FIG. 2A is a flowchart of a substrate processing process according to one embodiment of the present invention, and FIGS. 2B through 2D are cross-sectional configuration views of wafers after each substrate processing process is performed.

FIG. 3A is a flowchart of a conventional substrate processing process, and FIGS. 3B through 3E are cross-sectional configuration views of wafers after each substrate processing process is performed.

FIG. 4 is a graphic diagram illustrating the results of evaluation of leakage current in a capacitor structure according to Example 1.

FIG. 5A and 5B are graphic diagrams illustrating the results of XPS analysis in an interface between a wafer and a TiN film and an interface between the TiN film and a ZrO film according to Example 2, respectively.

FIG. 6 is a schematic cross-sectional view of a substrate processing apparatus according to another embodiment of the present invention.

FIG. 7 is a schematic cross-sectional view of a substrate processing apparatus according to still another embodiment of the present invention.

FIG. 8 is a schematic cross-sectional view of a substrate processing apparatus according to yet another embodiment of the present invention.

### DETAILED DESCRIPTION OF THE PREFERRED EMBODIMENTS

### One Embodiment of the Present Invention

Hereinafter, one embodiment of the present invention will be described.

### (1) Configuration of Substrate Processing Apparatus

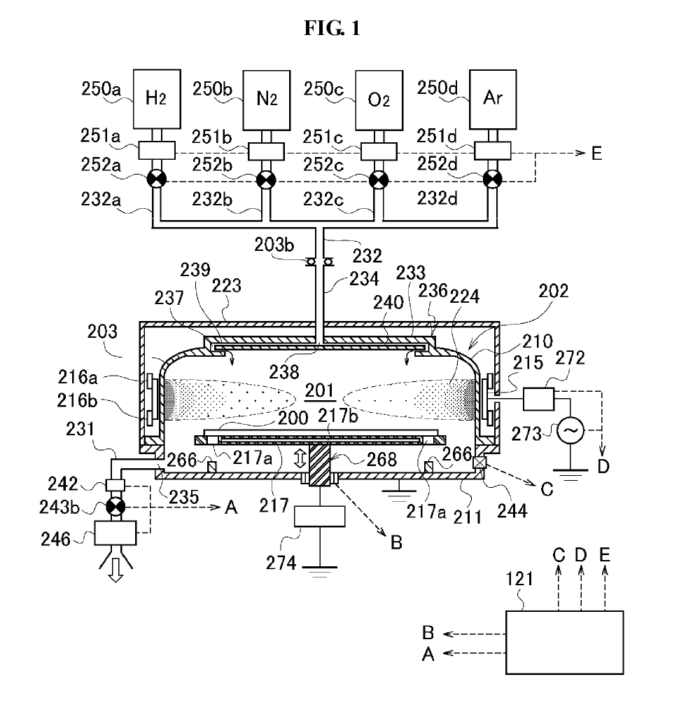

First, an example of a configuration of a substrate processing apparatus in which a method of manufacturing a semiconductor device according to this embodiment is performed will be described with reference to FIG. 1. FIG. 1 is a cross-sectional configuration view of a substrate processing apparatus configured as a modified magnetron-typed (MMT) device. The MMT device is, for example, configured to plasma-process a wafer 200 serving as a substrate made of silicon using an MMT plasma source which can generate high-density plasma by means of an electric field and a magnetic field.

The substrate processing apparatus according to this embodiment includes a process furnace 202 configured to plasma-process the wafer 200. The process furnace 202 includes a process container 203 constituting a process chamber 201, a susceptor 217, a gate valve 244, a shower head 236, a gas exhaust port 235, a cylindrical electrode 215, an upper magnet 216a, a lower magnet 216b and a controller 121.

The process container 203 constituting the process chamber 201 includes a dome-like upper container 210 which is a first container, and a bowl-like lower container 211 which is a second container. Then, the process chamber 201 is formed by covering the lower container 211 with the upper container 210. The upper container 210 is, for example, formed of a non-metal material such as aluminum oxide (Al₂O₃) or quartz (SiO₂), and the lower container 211 is, for example, formed of aluminum (Al).

The susceptor 217 configured to support the wafer 200 is disposed at a lower central region in the process chamber 201. The susceptor 217 is, for example, formed of a non-metal material such as aluminum nitride (AlN), ceramics or quartz so as to reduce contamination of metals in a film formed on the wafer 200. Since a heater 217b serving as a heating mechanism is integrally embedded in the susceptor 217, the heater 217b may heat the wafer 200. When electric power is supplied to the heater 217b, a surface of the wafer 200 is, for example, heated to approximately 50° C. to 400° C. In general, a substrate support according to this embodiment includes the susceptor 217 and the heater 217b.

The susceptor 217 is electrically insulated from the lower container 211. A second electrode (not shown) serving as an electrode configured to change impedance is equipped in the susceptor 217. The second electrode is installed via an impedance variable mechanism 274. The impedance variable mechanism 274 includes a coil or a variable condenser, and may control an electric potential of the wafer 200 via the second electrode (not shown) and the susceptor 217 by controlling the pattern number of the coil or a capacity value of the variable condenser.

A susceptor lift mechanism 268 configured to lift the susceptor 217 is installed at the susceptor 217. Through-holes 217a are installed at the susceptor 217. At least three wafer lift pins 266 configured to push up the wafer 200 are installed at a bottom surface of the above-described lower container 211. Then, the through-holes 217a and the wafer lift pins 266 are disposed so that the wafer lift pins 266 pass through the through-holes 217a in a non-contact state with the susceptor 217 when the susceptor 217 is lowered by the susceptor lift mechanism 268.

The gate valve 244 serving as an opening/closing valve is installed at a sidewall of the lower container 211. When the gate valve 244 is open, the wafer 200 may be loaded into the process chamber 201 using a transfer mechanism (not shown), or the wafer 200 may be unloaded from the process chamber 201. An inside of the process chamber 201 may be hermetically blocked by closing the gate valve 244.

The shower head 236 configured to supply a gas into the process chamber 201 is installed above the process chamber 201. The shower head 236 includes a cap-shaped lid 233, a gas introduction unit 234, a buffer chamber 237, a shielding plate 240 and a gas discharge port 239. A downstream end of a gas supply pipe 232 is connected to an upstream end of the gas introduction unit 234 via an O-ring 203b serving as an encapsulation member. An opening 238 through which a gas is supplied into the buffer chamber 237 is installed at a downstream end of the gas introduction unit 234. The buffer chamber 237 functions as a dispersion space configured to disperse a gas introduced into the buffer chamber 237 from the gas introduction unit 234.

A downstream end of a hydrogen gas supply pipe 232a configured to supply a hydrogen atom-containing gas such as, for example, H₂ gas, a downstream end of a nitrogen gas supply pipe 232b configured to supply a nitrogen atom-containing gas such as, for example, N₂ gas, a downstream end of an oxygen gas supply pipe 232c configured to supply an oxygen atom-containing gas such as, for example, O₂ gas, and a downstream end of a rare gas supply pipe 232d configured to supply Ar gas, which is a rare gas serving as an inert gas, are joined and connected to an upstream side of the gas supply pipe 232.

A hydrogen gas cylinder 250a, a mass flow controller 251a serving as a flow rate control device, and a valve 252a serving as an opening/closing valve are sequentially connected to the hydrogen gas supply pipe 232a from an upstream thereof. A nitrogen gas cylinder 250b, a mass flow controller 251b and a valve 252b valve are sequentially connected to the nitrogen gas supply pipe 232b from an upstream thereof. An oxygen gas cylinder 250c, a mass flow controller 251c and a valve 252c are sequentially connected to the oxygen gas supply pipe 232c from an upstream thereof. An Ar gas cylinder 250d, a mass flow controller 251d and a valve 252d are sequentially connected to the rare gas supply pipe 232d from an upstream thereof. The gas supply pipe 232, the hydrogen gas supply pipe 232a, the nitrogen gas supply pipe 232b, the oxygen gas supply pipe 232c and the rare gas supply pipe 232d are, for example, made of a non-metal material such as quartz or aluminum oxide, and a metal material such as SUS.

Generally, a gas introduction unit according to this embodiment includes the shower head 236, the O-ring 203b, the gas introduction unit 234, the gas supply pipe 232, the hydrogen gas supply pipe 232a, the nitrogen gas supply pipe 232b, the oxygen gas supply pipe 232c, the rare gas supply pipe 232d, the hydrogen gas cylinder 250a, the nitrogen gas cylinder 250b, the oxygen gas cylinder 250c, the Ar gas cylinder 250d, the mass flow controllers 251a through 251d and the valves 252a through 252d. The gas introduction unit is configured to supply Ar gas or a reactive gas, which includes at least one of H₂ gas and N₂ gas and O₂ gas, into the process chamber 201 via the buffer chamber 237 while a flow rate is controlled by means of the mass flow controllers 251a through 251d by opening/closing the valves 252a through 252d. Also, the gas including at least one of H₂ gas and N₂ gas and O₂ gas refers to one of a gas including O₂ gas and H₂ gas, a gas including O₂ gas and N₂ gas, and a gas including O₂ gas, H₂ gas and N₂ gas. That is, a gas in which at least one of H2 gas and N2 gas is added to underlying O2 gas is meant to be used as the reactive gas.

The gas exhaust port 235 configured to exhaust an inside of the process chamber 201 is installed at a lower sidewall portion of the lower container 211. An upstream end of a gas exhaust pipe 231 is connected to the gas exhaust port 235. An APC 242 serving as a pressure regulator, a valve 243b serving as an opening/closing valve, and a vacuum pump 246 serving as an exhaust device are sequentially installed at the gas exhaust pipe 231 from an upstream thereof. In general, a gas exhaust unit according to this embodiment includes the gas exhaust port 235, the gas exhaust pipe 231, the APC 242, the valve 243b and the vacuum pump 246. The gas exhaust unit is configured to exhaust an inside of the process chamber 201 by operating the vacuum pump 246 and opening the valve 243b. Also, the gas exhaust unit is configured to regulate a pressure value in the process chamber 201 by regulating an opening degree of the APC 242.

The cylindrical electrode 215 serving as a first electrode is installed at an outer circumference of the process container 203 (the upper container 210) to surround a plasma generating region 224 in the process chamber 201. The cylindrical electrode 215 is formed in a tube shape, for example, a cylindrical shape. The cylindrical electrode 215 is connected to a high-frequency power source 273 configured to generate high-frequency electric power via a matching box 272 configured to perform impedance matching. The cylindrical electrode 215 functions as a discharge mechanism configured to plasma-excite a gas supplied into the process chamber 201.

The upper magnet 216a and the lower magnet 216b are installed at upper and lower ends of an outer surface of the cylindrical electrode 215, respectively. Each of the upper magnet 216a and the lower magnet 216b is configured as a permanent magnet having a tube shape, for example, a ring shape. Each of the upper magnet 216a and the lower magnet 216b has magnetic poles formed at both ends (i.e., an inner circumferential end and an outer circumferential end of each magnet) of the process chamber 201 in a radial direction thereof. The magnetic poles of the upper magnet 216a and the lower magnet 216b are disposed so that the magnetic poles are opposite to each other. That is, inner circumferential portions of the upper magnet 216a and the lower magnet 216b have different magnetic poles. Therefore, lines of magnetic force are formed in a cylindrical axial direction along an inner surface of the cylindrical electrode 215.

Generally, a plasma generation unit according to this embodiment includes the cylindrical electrode 215, the matching box 272, the high-frequency power source 273, the upper magnet 216a and the lower magnet 216b. Magnetron discharge plasma is generated in the process chamber 201 by supplying a reactive gas, which includes at least one of H₂ gas and N₂ gas and O₂ gas, into the process chamber 201, and then supplying high-frequency electric power to the cylindrical electrode 215 to form an electric field while forming a magnetic field using the upper magnet 216a and the lower magnet 216b. In this case, as emitted electrons are rotated by the above-described electric field and magnetic field, an ionization rate of plasma may be increased, and high-density plasma having a long life-span may be generated.

A metallic shielding plate 223 configured to effectively shield an electric field, a magnetic field and electromagnetic waves is installed around the cylindrical electrode 215, the upper magnet 216a and the lower magnet 216b so that the electric field, the magnetic field and the electromagnetic waves generated by the cylindrical electrode 215, the upper magnet 216a and the lower magnet 216b do not have an adverse effect on external environments or other devices such as a process furnace.

The controller 121 serving as a control unit is configured to control operations of the APC 242, the valve 243b and the vacuum pump 246 through a signal line A, an operation of the susceptor lift mechanism 268 through a signal line B, an operation of the gate valve 244 through a signal line C, operations of the matching box 272 and the high-frequency power source 273 through a signal line D, operations of the mass flow controllers 251a through 251d and the valves 252a through 252d through a signal line E, and an amount of electric current transferred to the heater 217b or an impedance value of the impedance variable mechanism 274 through a signal line (not shown).

### (2) Substrate Processing Process

Next, a substrate processing process, which is performed as one process of the semiconductor manufacturing method according to this embodiment, will be described. This process is performed by the above-described substrate processing apparatus configured as the MMT device. Also, in the following description, operations of parts constituting the substrate processing apparatus are controlled by the controller 121.

In this case, one case where the wafer 200, which includes a TiN film serving as a metal element-containing film formed as a lower electrode of a capacitor, and a high-k film serving as an insulating film formed as a capacitor insulating film on the TiN film, is treated with plasma will be described. That is, one case where the TiN film formed on the wafer 200 and the high-k film formed on the TiN film are independently subjected to a modification process after formation of the high-k film will be described.

### Loading Wafer

First, the susceptor 217 is lowered to a transfer position of the wafer 200 to pass the wafer lift pins 266 through the through-holes 217a of the susceptor 217. As a result, the lift pins 266 protrude from a surface of the susceptor 217 by a predetermined height. Next, the gate valve 244 is opened to load the wafer 200 in the process chamber 201 using a transfer mechanism (not shown). As a result, the wafer 200 is supported in a horizontal posture on the wafer lift pins 266 protruding from the surface of the susceptor 217.

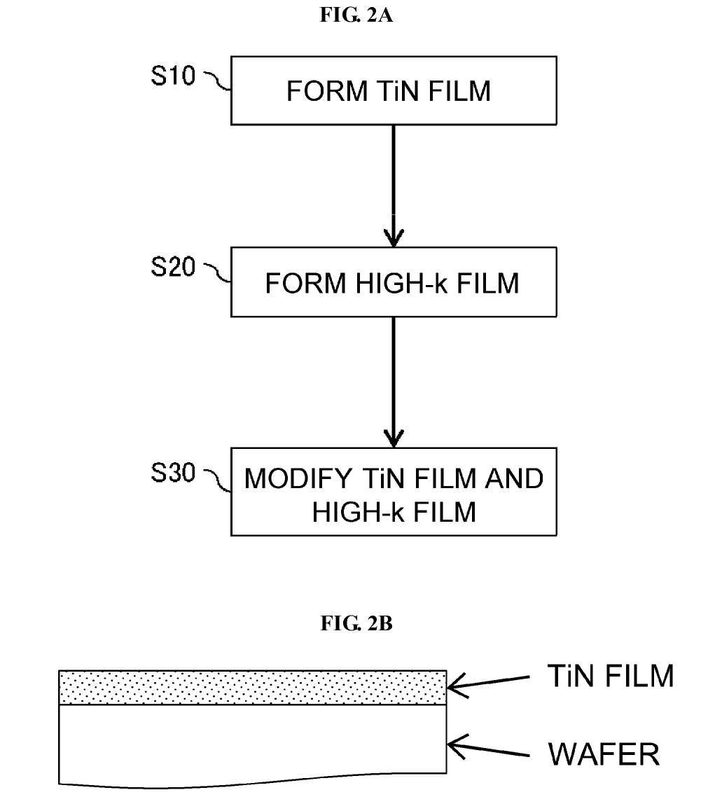

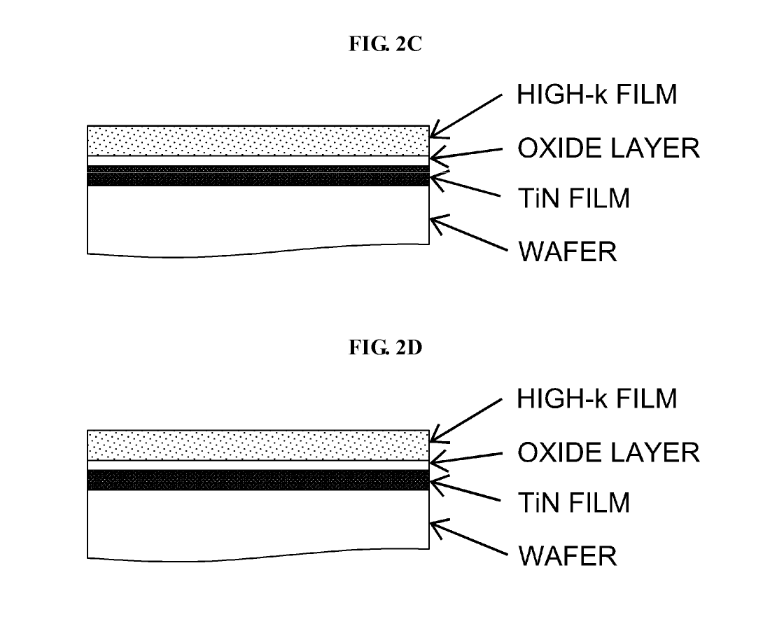

The TiN film serving as a lower electrode is previously formed on the wafer 200 (see Step S10 of FIG. 2A and FIG. 2B). Also, the high-k film serving as a capacitor insulating film, such as an aluminum oxide (Al₂O₃) film, a zirconium oxide (ZrO₂) film or a hafnium oxide (HfO₂) film, is previously formed on the TiN film (see Step S20 of FIG. 2A and FIG. 2C).

The TiN film is, for example, formed using a chemical vapor deposition (CVD) method or an atomic layer deposition (ALD) method in which a Ti source such as titanium tetrachloride (TiCl₄) gas and a nitriding agent such as ammonia (NH₃) gas is supplied onto the wafer 200.

Also, the high-k film is, for example, formed using the CVD or ALD method in which a metal element-containing gas, which is obtained by vaporizing an organic metal material such as tri-methyl-aluminum (TMA: Al(CH₃)₃), tetrakis-dimethyl-amino-zirconium (TDMAZr: Zr(N(CH₃)₂)₄) or tetrakis-dimethyl-amino-hafnium (TDMAHf: Hf(N(CH₃)₂)₄), all of which include a metal element such as Al, Zr or Hf, and an oxidant such as oxygen (O₂) gas or ozone (O₃) gas are supplied onto the TiN film. Also, when the high-k film is formed, a peripheral surface of the TiN film is oxidized by the oxidant used to form the high-k film. As a result, an oxide layer may be formed in an interfacial region between the TiN film and the high-k film (see FIG. 2C).

Impurities such as chlorine (Cl) included in TiCl₄ gas may remain in the TiN film formed using the above-described method. In the conventional substrate processing process, for the purpose of removal of the impurities remaining in the TiN film, a modification process (nitridation) of supplying hydrogen atoms and nitrogen atoms activated by plasma to the TiN film was performed before formation of the high-k film. Therefore, the wafer 200 to be processed in this embodiment is not subjected to this modification process. That is, after the formation of the TiN film, the high-k film is continuously formed without performing a modification process. Therefore, the modification process is not performed on the TiN film.

When the wafer 200 is loaded into the process chamber 201, the transfer mechanism is retreated out of the process chamber 201, and the gate valve 244 is closed to hermetically seal an inside of the process chamber 201. Then, the susceptor 217 is raised using the susceptor lift mechanism 268. As a result, the wafer 200 is disposed on a surface of the susceptor 217. Thereafter, the susceptor 217 is raised to a predetermined position to raise the wafer 200 to a predetermined processing position.

### Heating Wafer

Next, a surface of the wafer 200 is heated to a predetermined temperature by supplying electric power to the heater 217b buried in the susceptor 217. In this case, a temperature of the wafer 200 is maintained at a temperature lower than a temperature in which the high-k film formed on the wafer 200 crystallizes. Particularly, when the high-k film is a ZrO₂ film or a HfO₂ film, the temperature of the wafer 200 is, for example, maintained at a temperature of 50° C. to 400° C., and preferably a temperature of 50° C. to 300° C. When the temperature of the wafer 200 is maintained at a temperature of 400° C. or lower, and preferably 300° C. or lower, crystallization of the high-k film formed on the wafer 200 may be suppressed. Also, when the temperature of the wafer 200 is maintained at a temperature of 50° C. or higher, modification of the TiN film and the high-k film, as will be described later, may be effectively performed.

### Introducing Reactive Gas

Hereinafter, one case using a mixed gas of O₂ gas, H₂ gas and N₂ gas, for example, as a reactive gas including at least one of H₂ gas and N₂ gas and O₂ gas will be described.

First, the valves 252c, 252a and 252b are opened to introduce (supply) a reactive gas, which is a mixed gas of O₂ gas, H₂ gas and N₂ gas, into the process chamber 201 via the buffer chamber 237. In this case, the supply of the O₂ gas, the H₂ gas and the N₂ gas into the process chamber 201 is initiated at the same time or the supply of the H₂ gas is initiated first. Also, opening degrees of the mass flow controllers 251c, 251a and 251b are adjusted so that flow rates of the O₂ gas, the H₂ gas and the N₂ gas reach predetermined flow rates, respectively. For example, a concentration of hydrogen included in the reactive gas is adjusted so that the concentration of hydrogen is two or more times that of oxygen. Also, a concentration of nitrogen is adjusted so that the concentration of nitrogen is 0.5 to 2 times that of hydrogen. Preferably, the concentration of nitrogen is equivalent to that of hydrogen. Therefore, when a concentration of hydrogen is set to A, a ratio of the concentrations of the hydrogen, the oxygen and the nitrogen in the reactive gas is hydrogen:oxygen:nitrogen=A:<0.5A:0.5A to 2A. Preferably, the concentrations of the hydrogen, the oxygen and the nitrogen are adjusted to a ratio of hydrogen: oxygen:nitrogen=1:0.5:1.

In addition, after the introduction of the reactive gas into the process chamber 201 is initiated, a pressure in the process chamber 201 is maintained, using the vacuum pump 246 and the APC 242, so that the pressure in the process chamber 201 reaches a pressure at which the H₂ gas in the process chamber 201 does not explode. Particularly, the pressure in the process chamber 201 is regulated so that the pressure in the process chamber 201 reaches a pressure range of 0.1 to 500 Pa, and preferably a pressure range of 0.1 to 300 Pa, for example, a pressure of 200 Pa.

### Exciting Reactive Gas

After the introduction of the reactive gas is initiated, high-frequency electric power is applied to the cylindrical electrode 215 via the matching box 272 from the high-frequency power source 273. As a result, a magnetron discharge is generated in the process chamber 201, and high-density plasma is generated in the plasma generating region 224 above the wafer 200. Also, electric power (plasma generating power) applied to the cylindrical electrode 215 is, for example, set to a range of 100 W to 1,000 W, and preferably a range of 100 W to 500 W. In this case, the impedance variable mechanism 274 is controlled to a predetermined impedance value.

The O₂ gas, the H₂ gas and the N₂ gas supplied into the process chamber 201 are excited and activated by maintaining the reactive gas in a plasma state as described above. Then, oxygen in excited state (O) atoms (hereinafter referred to as “oxygen radical (O*)”), hydrogen in excited state (H) atoms (hereinafter referred to as “hydrogen radical (H*)”), and nitrogen in excited state (N) atoms (hereinafter referred to as “nitrogen radical (N*)”) are supplied to the TiN film and the high-k film formed on the wafer 200.

As the oxygen radical (O*) is supplied to the high-k film, the high-k film is modified into a film having a stoichiometric compositional ratio (stoichiometric film). For example, when the high-k film is composed of a ZrO₂ film, the oxygen radical (O*) is supplied to the ZrO₂ film. As a result, oxygen (O) atoms which are deficient in the ZrO₂ film are supplemented, so that a compositional ratio of the ZrO₂ film becomes close to the stoichiometric compositional ratio.

In addition, as the hydrogen radical (H*) and the nitrogen radical (N*) are supplied to the TiN film, separation of oxygen (O) from the TiN film and nitridation of the TiN film are promoted. That is, the hydrogen radical (H*) reaches the TiN film via the high-k film, and oxygen (O) atoms remaining in the TiN film are separated by a hydrogen reduction reaction. Then, the nitrogen (N) atoms are bound to dangling bonds generated by separation of the oxygen (O) atoms, and nitridation of the TiN film is promoted, thereby improving a film quality of the TiN film. Also, since the nitrogen radical (N*) has a high energy, the nitrogen radical (N*) has an effect of separating the impurities such as chlorine (Cl) atoms from the TiN film. Then, the nitrogen (N) atoms are bound to dangling bonds generated by separation of the impurities, and nitridation of the TiN film is promoted, thereby further improving a film quality of the TiN film.

That is, by supplying a reactive gas, which includes at least one of the oxygen radical (O*) and the hydrogen radical (H*), to a stacked film of the TiN film and the high-k film, the impurities such as carbon (C) atoms and chlorine (Cl) atoms may be removed from the TiN film and the high-k film, respectively, by action of the hydrogen radical (H*), and the oxygen (O) atoms may also be supplied to the high-k film by action of the oxygen radical (O*).

Also, by supplying a reactive gas, which includes at least one of the oxygen radical (O*) and the nitrogen radical (N*), to a stacked film of the TiN film and the high-k film, the oxygen (O) atoms may be supplied to the high-k film by action of the oxygen radical (O*), and the impurities in the TiN film may be removed by action of the nitrogen radical (N*).

Then, by supplying a reactive gas, which includes the oxygen radical (O*), the hydrogen radical (H*) and the nitrogen radical (N*), to a stacked film of the TiN film and the high-k film as described in this embodiment, the above-described effects may be achieved.

As described above, in this embodiment, a flow rate of the H₂ gas included in the reactive gas is also higher than that of the O₂ gas included in the reactive gas. Therefore, a reducing power to the TiN film is increased, and oxidation of the TiN film is suppressed. That is, when a flow rate of the H₂ gas supplied into the process chamber 201 is higher than that of the O₂ gas, an amount of the hydrogen radical (H*) reaching the TiN film via the high-k film is increased more than that of the oxygen radical (O*) reaching the TiN film via the high-k film. Therefore, since a reduction reaction of the TiN film is predominantly performed, compared to the oxidation reaction of the TiN film, oxidation of the TiN film is suppressed. Also, the hydrogen radical (H*) generally has a shorter life span than the oxygen radical (O*) (a shorter period in which an excited state can be maintained), and a lower activity than the oxygen radical (O*) (a weaker bonding force). Therefore, when the flow rate of the H₂ gas included in the reactive gas is lower than that of the O₂ gas, a reducing power to the TiN film may not be sufficiently high, and thus oxidation of the TiN film may be insufficiently suppressed. On the other hand, according to this embodiment, since the flow rate of the H₂ gas included in the reactive gas is higher than that of the O₂ gas, these problems may be solved.

### Exhausting Residual Gas

After a lapse of a predetermined processing time, for example, a processing time of 10 seconds to 240 seconds, and preferably 30 seconds to 120 seconds, when the modification of the TiN film and the high-k film is completed, the supply of electric power to the cylindrical electrode 215 is stopped. Then, while an inside of the process chamber 201 continues to be exhausted through the gas exhaust pipe 231, the valves 252c, 252a and 252b are closed to stop the supply of the reactive gas into the process chamber 201. In this case, the valve 252d is opened to supply Ar gas or N₂ gas serving as an inert gas into the process chamber 201, there by promoting the exhaust of the reactive gas from an inside of the process chamber 201. The Ar gas is preferably used as the inert gas.

Then, the susceptor 217 is lowered to a transfer position of the wafer 200, and the wafer 200 is supported on the wafer lift pin 266 protruding from a surface of the susceptor 217. Then, the gate valve 244 is opened, and the wafer 200 is unloaded from the process chamber 201 using a transfer mechanism (not shown). Accordingly, the substrate processing process according to this embodiment is completed. As described above, the conditions such as a temperature, a pressure in the process chamber 201, a flow rate of each gas, electric power applied to the cylindrical electrode 215, and a processing time are also optionally regulated according to a material of a film to be modified, and a film thickness.

### (3) Effects according to This Embodiment

This embodiment has one or more effects, as follows.

(a) According to this embodiment, after the TiN film and the high-k film are continuously formed, the TiN film and the high-k film may be sufficiently modified by subjecting both the TiN film and the high-k film to a modification process. That is, after the TiN film and the high-k film are continuously formed on the wafer 200, a reactive gas including oxygen radical (O*), hydrogen radical (H*) and nitrogen radical (N*) may be supplied onto the wafer 200 to modify the high-k film into a film having a stoichiometric compositional ratio (stoichiometric film), and promote the exhaust of the impurities from the TiN film and the nitridation of the TiN film as well.

(b) According to this embodiment, as modification processes, which have been performed, respectively, after formation of the TiN film and after formation of the high-k film as known in the art, are performed together on the TiN film and the high-k film after formation of the high-k film, the substrate processing process may be simplified.

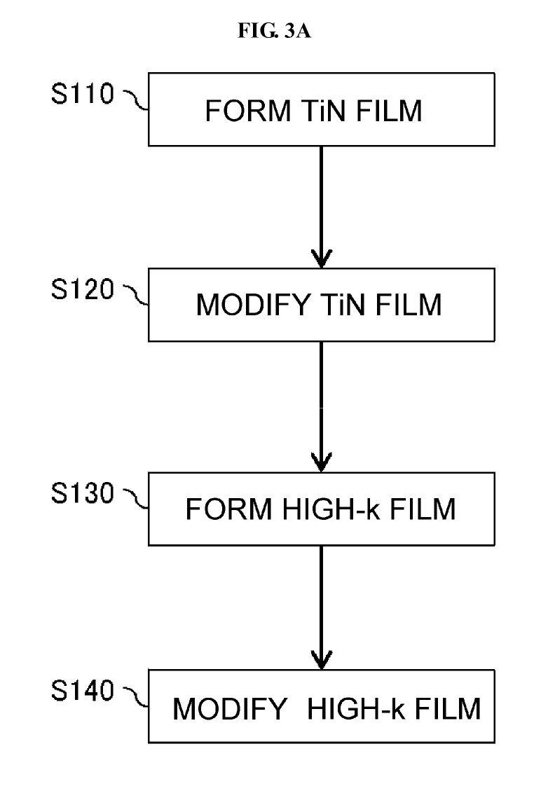

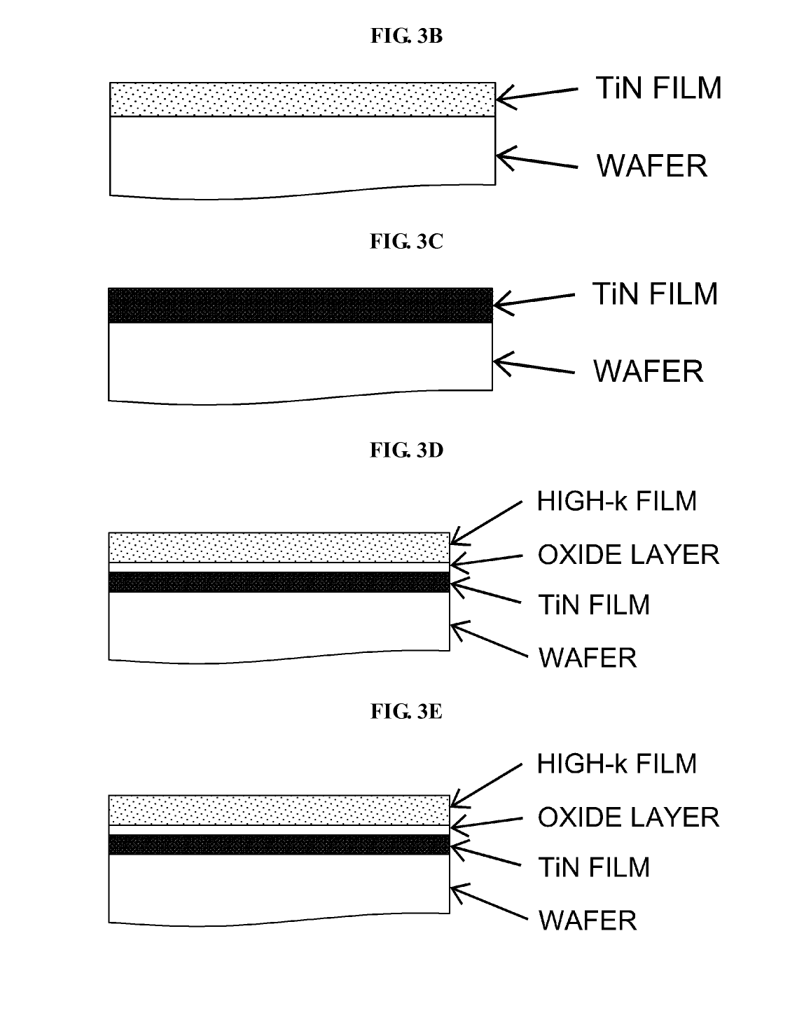

FIG. 2A is a flowchart of a substrate processing process according to this embodiment, and FIGS. 2B through 2D are cross-sectional configuration views of wafers after each substrate processing process is performed. In this embodiment, for a wafer in which the formation of the TiN film (S10) and the formation of the high-k film (S20) are continuously performed, a modification process is performed together on the TiN film and the high-k film (S30). That is, a modification process is performed once. Also, FIG. 3A is a flowchart of a conventional substrate processing process, and FIGS. 3B through 3E are cross-sectional configuration views of wafers after each substrate processing process is performed. In the conventional substrate processing process, after the formation of the TiN film is performed (S110), a modification process is performed on the TiN film (S120). Then, after the modification process, a high-k film is formed on the TiN film (S130), and a modification process is then performed on the high-k film (S140). That is, the modification process is performed twice.

As seen from comparison of these drawings, according to this embodiment, the substrate processing process may be simplified since modification of the TiN film is not performed before formation of the high-k film. Therefore, the manufacturing costs of the semiconductor device may be reduced.

(c) According to this embodiment, after introduction of the reactive gas into the process chamber 201 is initiated, a pressure in the process chamber 201 is regulated, using the vacuum pump 246 and the APC 242, so that the pressure in the process chamber 201 reaches a pressure range of 0.1 to 500 Pa, and preferably a pressure range of 0.1 to 300 Pa, for example a pressure of 200 Pa. By maintaining an inside of the process chamber 201 at such a pressure, explosion of the H₂ gas in the process chamber 201 may be prevented, and the substrate may be safely processed.

(d) According to this embodiment, the above-described substrate processing process is performed while a temperature of the wafer 200 is maintained at a temperature of, for example, 50° C. to 400° C., and preferably a temperature of 50° C. to 300° C. By maintaining the wafer 200 at such a temperature, modification of the TiN film and the high-k film may be effectively performed, and crystallization of the high-k film formed on the wafer 200 may also be suppressed.

(e) According to this embodiment, a flow rate of the H₂ gas included in the reactive gas is higher than that of the O₂ gas included in the reactive gas. Therefore, since a reducing power to the TiN film may be increased, oxidation of the TiN film may be suppressed. That is, the higher the flow rate of the H₂ gas supplied into the process chamber 201 is than that of the O₂ gas, the more an amount of the oxygen radical (O*) reaching the TiN film via the high-k film may be increased than that of the hydrogen radical (H*) reaching the TiN film via the high-k film. Therefore, a reduction reaction of the TiN film is more predominantly performed than the oxidation reaction of the TiN film, and oxidation of the TiN film is suppressed. Thus, characteristics of the semiconductor device may be improved by preventing an increase in resistance value of the TiN film.

(f) In the conventional modification process of the high-k film, in order to suppress the oxidation of the TiN film, for example, the processing conditions such as a flow rate or concentration of an oxidant should be controlled more strictly according to a film thickness or material of the high-k film. In this regard, in this embodiment, by allowing the H₂ gas to flow in the process chamber 201 in addition to the O₂ gas and increasing a flow rate of the H₂ gas compared to that of the O₂ gas as described above, the oxidation of the TiN film may be more easily suppressed, and the processing conditions may be relieved compared to the prior-art conditions.

(g) According to this embodiment, a modification process of the TiN film is performed after formation of the high-k film, rather than before formation of the high-k film. As a result, reduction in modification effect of the TiN film by formation of the high-k film may be avoided. That is, in a conventional substrate processing process in which a modification process of the TiN film is performed before formation of the high-k film, even the TiN film whose modification process is completed may be oxidized by an oxidant used to form the high-k film. Therefore, a modification effect on the TiN film may be reduced (made useless), but these problems may be solved according to this embodiment.

(h) According to this embodiment, high-density plasma is generated in the plasma generating region 224 arranged around the wafer 200, that is, arranged above the wafer 200, to generate the oxygen radical (O*), the hydrogen radical (H*) and the nitrogen radical (N*) in the process chamber 201. Therefore, since the generated radicals may be supplied onto the wafer 200 before the radicals lose activity, a modification rate may be improved. Also, in a remote plasma system where plasma is generated outside the process chamber 201 to generate radicals, the radicals easily lose activity before the radicals are supplied to the wafer 200, and a modification process may not be effectively performed.

### Other Embodiments of the Present Invention

Although the embodiments of the present invention have been described in detail, the present invention is not intended to be limited to the above-described embodiments, and various changes and modifications can be made without departing from the scope of the present invention.

For example, the present invention is not limited to a case using a gas including all of the O₂ gas, the H₂ gas and the N₂ gas as the reactive gas, and the present invention is preferably also applicable to a case using a gas including the O₂ gas and the H₂ gas (i.e., a gas which does not include the N₂ gas) or a gas including the O₂ gas and the N₂ gas (i.e., a gas which does not include the H₂ gas). As described above, when the reactive gas including at least the oxygen radical (O*) and the hydrogen radical (H*) is supplied to a stacked film of the TiN film and the high-k film, oxygen (O) atoms may be supplied to the high-k film while removing the impurities from the TiN film and the high-k film, respectively. Also, when the reactive gas including at least the oxygen radical (O*) and the nitrogen radical (N*) is supplied to the stacked film of the TiN film and the high-k film, the impurities in the TiN film may be removed while supplying the oxygen (O) atoms to the high-k film. As described in the above-described embodiment, the above-described effects may be achieved by supplying the reactive gas, which includes the oxygen radical (O*), the hydrogen radical (H*) and the nitrogen radical (N*), to the stacked film of the TiN film and the high-k film.

In addition, the above-described embodiment aims to modify both of the TiN film serving as the metal element-containing film and the high-k film serving as the insulating film, but the present invention is not limited to this case.

That is, when the film quality of the high-k film formed on the wafer 200 already meets quality requirements (when there is no need to modify the high-k film), a modification process may be performed for the purpose of modification of the TiN film. In this case, a mixed gas of H₂ gas and N₂ gas may be used as the reactive gas, and the O₂ gas may not be mixed in the reactive gas. When the reactive gas is used as described above, an oxygen component is not included in the reactive gas, thereby reliably preventing the oxidation of the TiN film.

Also, when the film quality of the TiN film formed on the wafer 200 already meets the quality requirements (when there is no need to modify the TiN film), a modification process may be performed for the purpose of modification of the high-k film. In this case, a mixed gas of H₂ gas and O₂ gas may be used as the reactive gas, and the N₂ gas may not be mixed in the reactive gas. In this case, since a nitrogen component is not included in the reactive gas, the nitridation of the high-k film may be reliably prevented.

In addition, in the above-described embodiment, the case where the high-k film is stacked on the TiN film has been described, but the present invention is not limited to such a case. The present invention is preferably applicable to a case where the TiN film is stacked on the high-k film, a case where the high-k film is stacked on the TiN film in a state where the TiN film is interposed between the high-k films, or a case where the TiN film and the high-k film are not stacked but arranged on the wafer 200. Further, the present invention is preferably applicable to a case of modifying a build-up film having a charge trap flash (CTF) structure in which a SiO film, a SiN film, a high-k film and a TaN film are, for example sequentially formed on the wafer 200.

Also, the case where the H₂ gas and the N₂ gas are used as the hydrogen atom-containing gas and the nitrogen atom-containing gas, respectively, and the mixed gas of H₂ gas and N₂ gas is used has been described in the above-described embodiment, but the present invention is not limited to such a case. Ammonia (NH₃) gas or monomethylhydrazine (CH₆N₂) may be used alone as the hydrogen atom- or nitrogen atom-containing gas, and a gas obtained by mixing the hydrogen atom- or nitrogen atom-containing gas, the H₂ gas and the N₂ gas at a certain ratio may also be used, depending on various conditions such as a processing temperature, a processing pressure, and a supply flow rate.

Further, in addition to the case where the O₂ gas is used as the oxygen atom-containing gas, ozone (O₃) gas or water vapor (H₂O) may be used herein. Since H₂O has a lower oxidizing power than an oxygen-containing material activated with O₃ or plasma, the oxidation of the lower electrode may be effectively prevented during film formation when the H₂O is used as an oxidant source. Even when other gases rather than the above-described H₂, N₂ and O₂ gases are used, the same effects may be achieved by increasing an amount of the hydrogen atoms compared to that of the oxygen atoms. For example, the same effects are achieved when the amount of the hydrogen atoms is approximately twice that of the oxygen atoms.

Also, the case where the metal element-containing film is, for example, configured as the TiN film has been described in the above-described embodiment, but the present invention is not limited to such a case. For example, the metal element-containing film may be configured as a TaN film or a WN film, which includes other metal elements such as tantalum (Ta) and tungsten (W). When a metal element-containing film to be modified is configured as the metal-containing nitride film containing the nitrogen (N) atoms, the above-described effects may be preferably achieved by supplying a reactive gas containing at least one of hydrogen radical (H*) and nitrogen radical (N*), and oxygen radical (O*). That is, when a metal element-containing film to be modified is configured as the metal-containing nitride film containing the nitrogen atoms and a film is also deficient in nitrogen, the nitrogen-deficient film may be supplemented with nitrogen in the metal element-containing film.

In addition, the case where the high-k film serving as the insulating film is, for example, configured as the Al₂O₃ film, the HfO₂ film or the ZrO₂ film has been described in the above-described embodiment, but the present invention is not limited to such a case. For example, the high-k film serving as the insulating film may be configured as a TiO₂ film, a Nb₂O₅ film, a Ta₂O₅ film, a SrTiO₃ film, a (Ba, Sr)TiO₃ film, or a lead zirconic acid titanate (PZT) film. That is, an insulating film to be modified may be configured as an oxide film made of one selected from Ta, Ti, Y, La, Ce, Ba, Sr and Pb in addition to Al, Hf and Zr, an oxide film made of at least two selected therefrom, or an oxide film containing Si and one selected therefrom. When the insulating film to be modified contains the impurities such as carbon (C) atoms or is deficient in oxygen, or a metal-containing oxide film or an oxy-nitride film is formed in an interface between the metal element-containing film and the insulating film, the above-described effects may be achieved by supplying the reactive gas containing at least one of hydrogen radical (H*) and nitrogen radical (N*), and oxygen radical (O*).

When the reactive gas is supplied into the process chamber 201, the valve 252d may be opened to supply the reactive gas together with Ar gas serving as a rare gas. Therefore, the conditions such as a concentration or flow velocity of a gas supplied into the process chamber 201 may be easily controlled without changing flow rates or ratios of the H₂ gas, the N₂ gas and the O₂ gas.

In the above-described embodiment, the case of processing the wafer 200 made of silicon has been described, but the present invention is not limited to such a case. Accordingly, other substrates such as a glass substrate may be processed in the same manner.

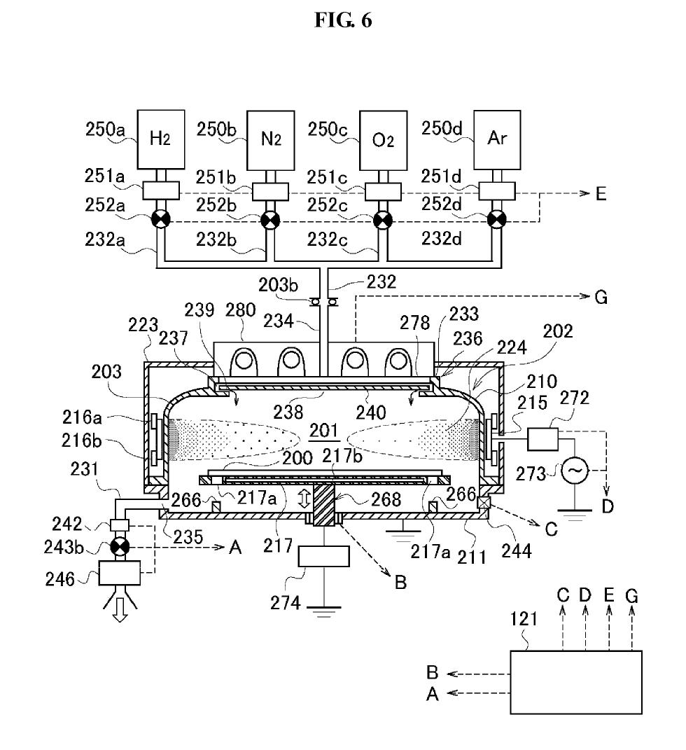

Also, the case where the wafer 200 is heated using the heater 217b installed in the susceptor 217 has been described in the above-described embodiment, the present invention is not limited to such a case. For example, the wafer 200 may be heated by irradiating infrared rays from a lamp heating mechanism 280, as shown in FIG. 6. In this case, the lamp heating mechanism 280 may be configured to irradiate light to an inside of the process chamber 201 via a light transmission window 278 installed above the process chamber 201, that is, installed on a surface of the upper container 210. When the heater 217b is used together with the lamp heating unit 280, the wafer 200 may be heated in a shorter time, compared to when only the heater 217b is used to heat the wafer 200. In addition, the wafer 200 may be heated using only the lamp heating unit 280 without installing the heater 217b.

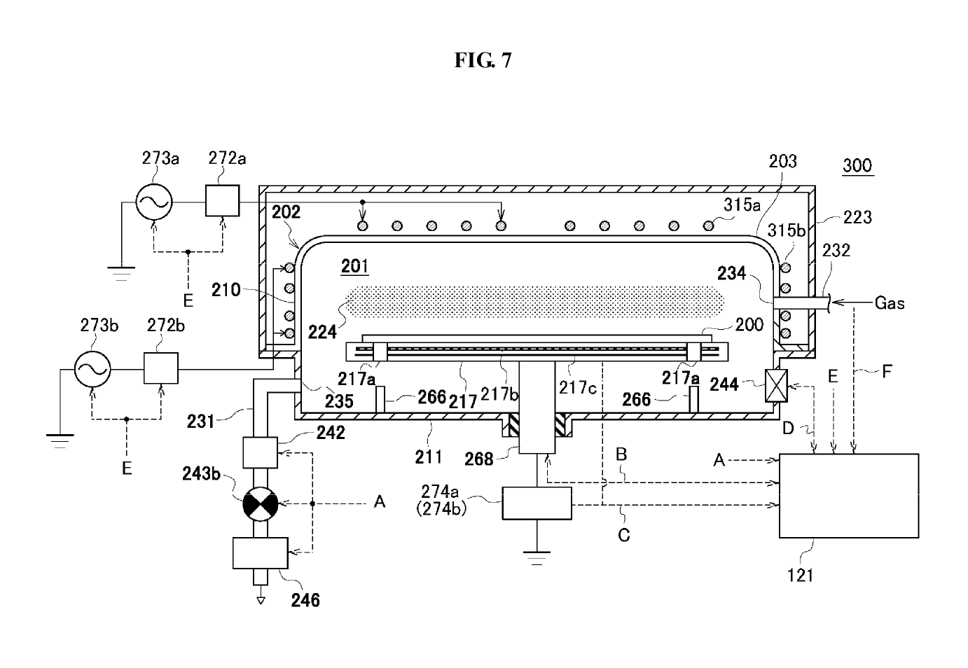

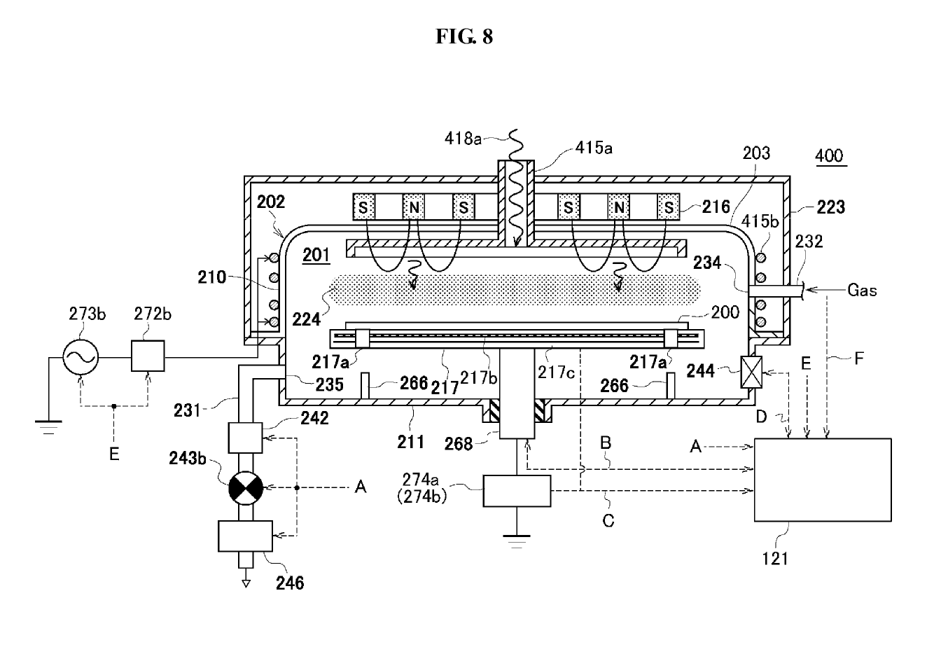

Furthermore, the case where the MMT device 100 is used as the substrate processing apparatus has been described in the above-described embodiment, but the present invention is not limited to such a case. For example, an inductively coupled plasma (ICP) device shown in FIG. 7 or an electron cyclotron resonance (ECR) device shown in FIG. 8 may be used as the substrate processing apparatus.

FIG. 7 is a schematic cross-sectional view of a plasma processing apparatus 300 configured as the substrate processing apparatus using an ICP system. The ICP device 300 is a part of a configuration of the plasma generation unit, and includes dielectric coils 315a and 315b configured to supply electric power to generate plasma. The dielectric coil 315a is constructed outside a ceiling wall of the upper container 210, and the dielectric coil 315b is constructed outside a circumferential wall of the upper container 210. In the ICP device 300, a reactive gas is also supplied into the process chamber 201 via the gas introduction port 234. When the reactive gas is supplied and high-frequency electric power is applied to the dielectric coils 315a and 315b, an electric field which is substantially horizontal to a surface (processed surface) of the wafer 200 is configured to be formed by electromagnetic induction. The electric field may be used as energy to cause a plasma discharge, and the reactive gas supplied into the process chamber 201 may be excited to generate oxygen radical (O*), hydrogen radical (H*) and nitrogen radical (N*). In the configuration, the intensities of a vertical ingredient and a horizontal ingredient of the electric field applied to the wafer 200 may be regulated by controlling the high-frequency electric power applied to the dielectric coils 315a and 315b, and the impedance of the impedance variable mechanism 274. In particular, an electric field in a horizontal direction is more easily strengthened by the dielectric coil 315b. Also, a cylindrical electrode in a tube shape or an electrode in a parallel flat plate shape may be, for example, used instead of the dielectric coil 315b. In general, a plasma generation unit includes the dielectric coils 315a and 315b, the matching boxes 272a and 272b, and the high-frequency power sources 273a and 273b.

FIG. 8 is a schematic cross-sectional view of a plasma processing device 400 configured as the substrate processing apparatus using an ECR system. The ECR device 400 is a part of a configuration of the plasma generation unit, and includes a microwave introduction pipe 415a and a dielectric coil 415b. The microwave introduction pipe 415a is constructed outside a ceiling wall of the upper container 210, and configured to supply microwaves 418a into the process chamber 201 to generate plasma. The dielectric coil 415b is constructed outside a circumferential wall of the upper container 210 and configured to supply electric power to generate plasma. In the case of the ECR device 400, a reactive gas is supplied into the process chamber 201 via the gas introduction port 234. When the reactive gas is supplied to introduce the microwaves 418a from the microwave introduction pipe 415a, an electric field, which is substantially vertical to a proceeding direction of the microwave 418a, that is, substantially horizontal to a surface (processed surface) of the wafer 200, is configured to be formed. Also, when high-frequency electric power is applied to the dielectric coil 415b, an electric field which is substantially horizontal to the processed surface of the wafer 200 is configured to be formed by electromagnetic induction. Therefore, an electric field formed by the microwaves 418a and the dielectric coil 415b may be used as energy to cause a plasma discharge, and a supplied reactive gas may be excited to generate oxygen radical (O*), hydrogen radical (H*) and nitrogen radical (N*). In the configuration, the intensities of a vertical ingredient and a horizontal ingredient of the electric field applied to the wafer 200 may be regulated by controlling an intensity of the introduced microwaves 418a, high-frequency electric power applied to the dielectric coil 415b, and impedance of the impedance variable mechanism 274. In particular, an electric field in a horizontal direction with respect to the processed surface of the wafer 200 is more easily strengthened by the dielectric coil 415b. Also, a cylindrical electrode in a tube shape or an electrode in a parallel flat plate shape may be, for example, used instead of the dielectric coil 415b. In addition, the microwave introduction pipe 415a may be installed at a sidewall portion of the upper container 210, and the microwaves 418a may be substantially horizontally radiated with respect to the surface of the wafer 200. According to this configuration, a direction of the electric field is easy to control with respect to the processed surface of the wafer 200. In general, a plasma generation unit includes the microwave introduction pipe 415a, the dielectric coil 415b, the matching box 272b, the high-frequency power source 273b and the magnet 216.

### EXAMPLES

### Example 1

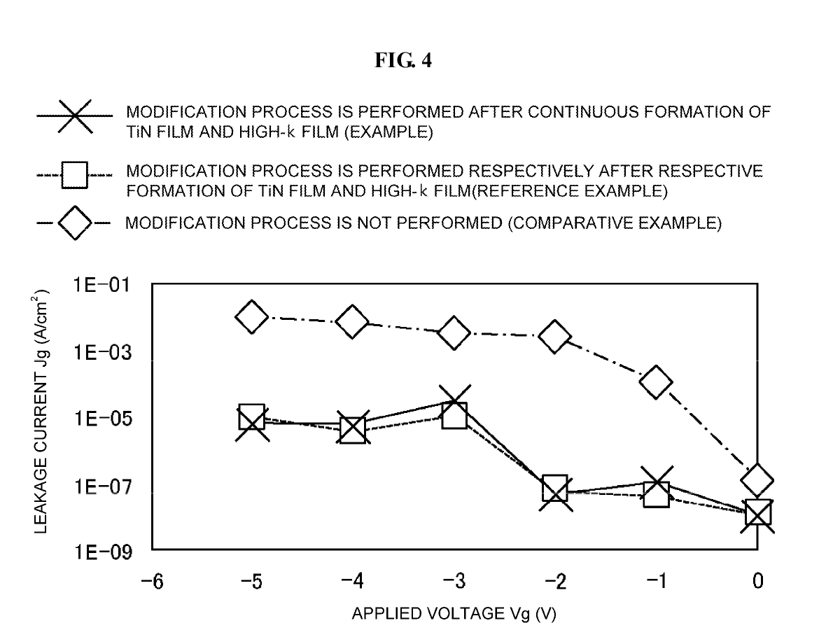

In this Example, a TiN film serving as a lower electrode was formed on a wafer, a high-k film serving as a capacitor insulating film was formed on the TiN film, and a TiN film serving as an upper electrode was formed on the high-k film. The high-k film was used as a ZrO₂ film having a thickness of 8 nm. Then, a voltage was applied between the upper electrode and the lower electrode, a value of leakage current which passes through the high-k film was determined FIG. 4 is a graphic diagram illustrating the results of evaluation of leakage current in a capacitor structure. A horizontal axis of FIG. 4 represents a voltage Vg (V) which is applied between the upper electrode and the lower electrode, and a vertical axis represents a leakage current value Jg (A/cm²) in a high-k film.

In the drawing, a symbol “x” indicates that a modification process is performed in the same manner as in the above-described embodiment after continuous formation of a TiN film serving as a lower electrode and a high-k film and before formation of a TiN film serving as an upper electrode (Example). In this Example, a wafer temperature was set to 150° C., a pressure in a process chamber was set to 200 Pa, a flow rate of O₂ gas was set to 0.5 slm, a flow rate of H₂ gas was set to 1.0 slm, a flow rate of N₂ gas was set to 0.5 slm, electric power (plasma generating power) applied to a cylindrical electrode was set to 200 W, and a processing time was set to 120 seconds. Also, in the drawing, a symbol “□” indicates that modification processes are performed, respectively, after formation of a TiN film serving as a lower electrode and after formation of a high-k film, and before formation of a TiN film serving as an upper electrode (Reference Example). In addition, in the drawing, a symbol “ ” indicates that modification processes are performed, respectively, after formation of a TiN film serving as a lower electrode and after formation of a high-k film (Comparative Example).

Referring to FIG. 4, it can be seen that, when the modification processes were performed (Example and Reference Example), the leakage current may be reduced and the TiN film and the high-k film may be modified together, compared to when the modification processes were not performed (Comparative Example). Also, it can be seen that, when the modification processes were performed together after the formation of the high-k film (Example), the leakage current may be reduced to a similar level obtained when the modification processes were performed, respectively, after the formation of the TiN film and after the formation of the high-k film (Reference Example), and a modification effect may be achieved at substantially the same level as in the Reference Example.

### Example 2

In this Example, a TiN film was formed on a wafer made of silicon (Si), and a ZrO₂ film was formed on the TiN film. Then, a stacked structure of the TiN film formed on the wafer and the ZrO₂ film was modified in the same manner as in the above-described embodiment. Thereafter, compositions of an interface between the wafer and the TiN film and an interface between the TiN film and the ZrO₂ film were measured, respectively, using X-ray photoelectron spectroscopy (XPS). Also, in the modification process, O₂ gas was used as a reactive gas. In addition, a wafer temperature (processing temperature) was varied from room temperature to 500° C.

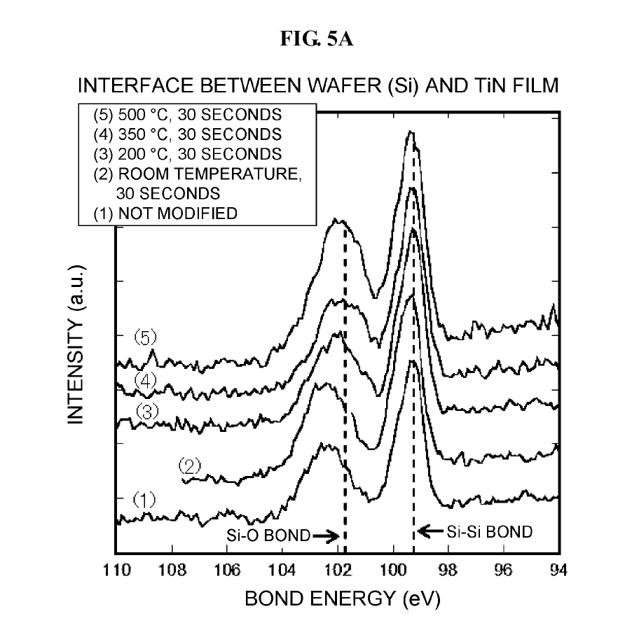

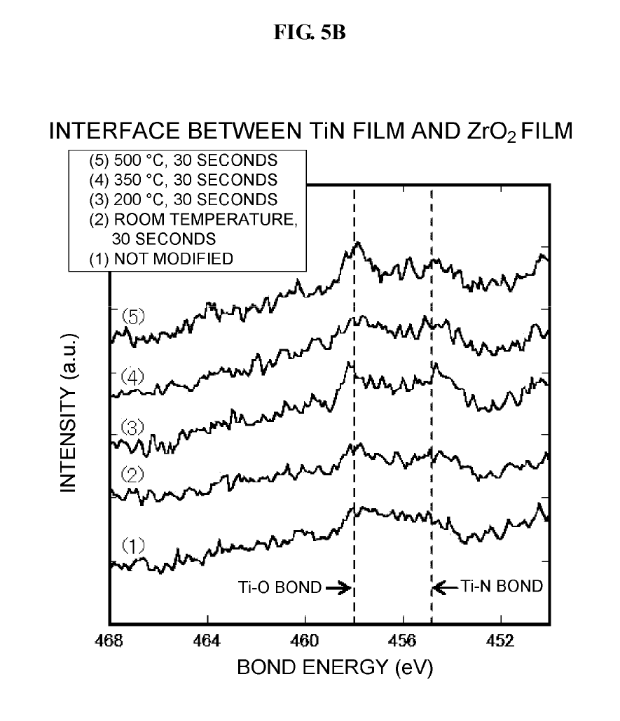

FIG. 5A and FIG. 5B are graphic diagrams illustrating the results of XPS analysis. Here, FIG. 5A shows the measurement results in an interface between a wafer and a TiN film, FIG. 5B shows the measurement results in an interface between the TiN film and a ZrO film. Each horizontal axis of FIG. 5A and FIG. 5B represents a bond energy (eV), and each vertical axis represents a measurement intensity (any intensity). Also, in the drawings, a line (1) indicates that a modification process was not performed, and lines (2) through (5) indicate that a modification process was performed at a wafer temperature, for example, room temperature, 200° C., 350° C. and 500° C. In the lines (2) through (5), a processing time (i.e. , a supply time of oxygen radical (O*) to a wafer) was set to 30 seconds.

Referring to FIG. 5A, it can be seen that, when the wafer temperature was set to 350° C. or higher (i.e., in the case of the lines (4) and (5)), a measurement intensity of an Si-Si bond was reduced in the interface between the wafer and the TiN film. Also, it can be seen that a measurement intensity of an Si—O bond was increased as energy of a peak indicative of the Si—O bond is shifted. That is, it can be revealed that, when the above-described modification process was performed on a stacked structure of the TiN film and the ZrO₂ film using O₂ gas, the oxygen radical (O*) was passed through the ZrO₂ film, and reached the interface between the wafer and the TiN film.

In addition, referring to FIG. 5B, it can be seen that, when the wafer temperature was set to room temperature, 200° C. and 300° C. (i.e., in the case of the lines (2) through (4)), neither a peak indicative of a Ti—O bond nor that of a Ti—N bond was shifted in the interface between the TiN film and the ZrO film. Also, it can be seen that, when the wafer temperature was set to 500° C. (i.e., in the case of the line (5)), a measurement intensity of the Ti—O bond was increased. That is, it can be seen that, when the above-described modification process was performed at the wafer temperature of 500° C., the TiN film may de degraded.

From the above-described results, it can be seen that the wafer temperature is preferably set to less than 500° C., and more preferably less than 350° C.

### Preferred Embodiments of the Present Invention

Hereinafter, preferred embodiments of the present invention will be additionally stated.

### Supplementary Note 1

According to one aspect of the present invention, there is provided a method of manufacturing a semiconductor device, including: loading a substrate having thereon a metal element-containing film and an insulating film formed on the metal element-containing film into a process chamber and supporting the substrate using a substrate support installed in the process chamber; supplying a reactive gas including at least one of hydrogen in excited state and nitrogen in excited state, and oxygen in excited state onto the substrate in the process chamber and processing the substrate; and unloading the substrate from an inside of the process chamber.

### Supplementary Note 2

Preferably, the processing of the substrate includes exhausting an atmosphere in the process chamber using an exhaust unit installed in the process chamber and maintaining a pressure in the process chamber to prevent an explosion of the hydrogen in the process chamber.

### Supplementary Note 3

Also, preferably, a pressure at which the hydrogen does not explode is in a range of 0.1 Pa to 500 Pa.

### Supplementary Note 4

In addition, preferably, the insulating film includes a high-k film, and the processing of the substrate includes maintaining a temperature of the substrate at a temperature lower than a temperature whereat the high-k film crystallizes using a substrate heating unit installed in the process chamber.

### Supplementary Note 5

Additionally, preferably, the metal element-containing film includes a nitrogen atom.

### Supplementary Note 6

Furthermore, preferably, an amount of hydrogen in excited state atoms included in the reactive gas is greater than that of oxygen in excited state atoms included in the reactive gas during the processing of the substrate.

### Supplementary Note 7

According to another aspect of the present invention, there is provided a substrate processing apparatus including: a process chamber wherein a substrate including a metal element-containing film and an insulating film formed on the metal element-containing film is loaded; a substrate support configured to support and heat the substrate in the process chamber; a gas introduction unit configured to supply a reactive gas including at least one of hydrogen in excited state and nitrogen in excited state, and oxygen in excited state into the process chamber; a plasma generation unit configured to excite the reactive gas in the process chamber; and a control unit configured to control the substrate support, the gas introduction unit and the plasma generation unit.

### Supplementary Note 8

According to still another aspect of the present invention, there is provided a method of manufacturing a semiconductor device, including: loading a substrate having thereon a metal element-containing film and an insulating film formed on the metal element-containing film into a process chamber and supporting the substrate using a substrate support installed in the process chamber; supplying a reactive gas including at least one of nitrogen in excited state and oxygen in excited state, and hydrogen in excited state onto the substrate in the process chamber and processing the substrate; and unloading the substrate from an inside of the process chamber.

### Supplementary Note 9

According to yet another aspect of the present invention, there is provided a method of manufacturing a semiconductor device, including:

loading a substrate having thereon an insulating film and a metal element-containing film formed on the insulating film into a process chamber and supporting the substrate using a substrate support installed in the process chamber; supplying a reactive gas including at least one of nitrogen in excited state and oxygen in excited state, and hydrogen in excited state onto the substrate in the process chamber and processing the substrate; and unloading the substrate from an inside of the process chamber.

### Supplementary Note 10

Preferably, the metal element-containing film is a nitride film.

### Supplementary Note 11

Also, preferably, the metal element-containing film is a titanium element-containing film.

### Supplementary Note 12

In addition, preferably, the insulating film includes a high-k film, and the processing of the substrate includes heating the substrate at a temperature at which the high-k film does not crystallize using the substrate support.

### Supplementary Note 13

Additionally, preferably, an amount of the hydrogen in excited state included in the reactive gas is greater than that of the oxygen in excited state included in the reactive gas during the processing of the substrate.

### Supplementary Note 14

Also, preferably, a concentration of the hydrogen atoms in the reactive gas is two or more times that of the oxygen atoms.

### Supplementary Note 15

In addition, preferably, a concentration of the nitrogen atoms in the reactive gas is 0.5 to 2 times that of the hydrogen atoms.

### Supplementary Note 16

Additionally, preferably, a ratio of the concentrations of the hydrogen atoms, the oxygen atoms and the nitrogen atoms in the reactive gas is 1:0.5:1.

### Supplementary Note 17

Furthermore, preferably, the metal element-containing film included in the substrate loaded into the process chamber is not subjected to a modification process.

### Supplementary Note 18

According to yet another aspect of the present invention, there is provided a substrate processing apparatus including: a process chamber wherein a substrate including a metal element-containing film and an insulating film formed on the metal element-containing film is loaded;

a substrate support configured to support and heat the substrate in the process chamber;

a gas introduction unit configured to supply a reactive gas including at least one of nitrogen in excited state and oxygen in excited state, and hydrogen in excited state into the process chamber;

a plasma generation unit configured to excite the reactive gas in the process chamber; and

a control unit configured to control the substrate support, the gas introduction unit and the plasma generation unit.

1. A method of manufacturing a semiconductor device, comprising:
loading a substrate having thereon a metal element-containing film and an insulating film formed on the metal element-containing film into a process chamber and supporting the substrate using a substrate support installed in the process chamber;
supplying a reactive gas including at least one of hydrogen in excited state and nitrogen in excited state, and oxygen in excited state onto the substrate in the process chamber and processing the substrate; and
unloading the substrate from an inside of the process chamber.

2. The method according to claim 1, wherein the processing of the substrate comprises maintaining a pressure in the process chamber to prevent an explosion of the hydrogen in the process chamber by exhausting an atmosphere in the process chamber.

3. The method according to claim 1, wherein the insulating film comprises a high-k film, and
the processing of the substrate comprises maintaining a temperature of the substrate at a temperature lower than a temperature whereat the high-k film crystallizes.

4. The method according to claim 1, wherein the metal element-containing film comprises a nitrogen atom.

5. The method according to claim 1, wherein an amount of the hydrogen in excited state included in the reactive gas is greater than that of the oxygen in excited state included in the reactive gas during the processing of the substrate.
